(19) United States
(12) Patent Application Publication
(10) Pub. No.: US 2026/0126724 A1
(43) Pub. Date: May 7, 2026

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Sumin JANG, Suwon-si (KR); Soobin LIM, Suwon-si (KR); Joonhee HAN, Suwon-si (KR); Yunju CHAE, Suwon-si (KR); Jimin KIM, Suwon-si (KR); Hyun LEE, Suwon-si (KR); Kyungmog KIM, Suwon-si (KR); Ahra CHO, Suwon-si (KR)

(21) Appl. No.: 19/379,501

(22) Filed: Nov. 4, 2025

(30) Foreign Application Priority Data
Nov. 6, 2024 (KR) 10-2024-0156547

(51) Int. Cl. G03F 7/004; C07F 7/22; G03F 7/00; H01L 21/311; H01L 21/3213

(52) U.S. Cl. CPC G03F 7/0042; C07F 7/2224; C07F 7/226; G03F 7/70033; H10P 50/71; H10P 50/73

(57) ABSTRACT

A semiconductor photoresist composition and a method of forming or providing patterns utilizing the semiconductor photoresist composition are disclosed. The semiconductor photoresist composition may include an organometallic compound represented by Chemical Formula 1 and a solvent.

### CROSS-REFERENCE TO RELATED APPLICATION

The present application claims priority to and the benefit of Korean Patent Application No. 10-2024-0156547, filed on Nov. 6, 2024, in the Korean Intellectual Property Office, the entire disclosure of which is incorporated herein by reference.

### BACKGROUND

### 1. Field

One or more embodiments of the present disclosure relate to a semiconductor photoresist composition and a method of forming or providing patterns utilizing the semiconductor photoresist composition.

### 2. Description of the Related Art

Extreme ultraviolet (EUV) lithography is paid attention to as one essential technology to manufacture a next generation semiconductor device. The EUV lithography is a pattern-forming technology using an EUV ray having a wavelength of 13.5 nm as an exposure light source. According to the EUV lithography, an extremely fine pattern (e.g., less than or equal to 20 nm) may be formed or provided in an exposure process during a manufacture of a semiconductor device.

The extreme ultraviolet (EUV) lithography is realized through development of compatible photoresists which can be performed at a spatial resolution of less than or equal to 16 nm. Efforts to satisfy insufficient or unsuitable specifications of chemically amplified (CA) photoresists that are generally available, such as a resolution, a photospeed, and feature roughness (or also referred to as a line edge roughness or LER), for the next generation device are being made.

An intrinsic image blurring due to an acid catalyzed reaction in the polymer-type or kind photoresists limits a resolution in small feature sizes, which has been experienced in electron beam (e-beam) lithography for a long time. The chemically amplified (CA) photoresists are designed for high sensitivity, but because their elemental makeups reduce light absorbance of the photoresists at a wavelength of 13.5 nm and thus decrease their sensitivity, the chemically amplified (CA) photoresists may partially have more difficulties under an EUV exposure.

Also, the CA photoresists may have difficulties in the small feature sizes due to roughness issues, and line edge roughness (LER) of the CA photoresists experimentally turns out to be increased, as a photospeed is decreased partially due to an essence of acid catalyst processes. Accordingly, a novel high-performance photoresist is required or desired in a semiconductor industry because of these defects and problems of the CA photoresists.

In order to overcome the drawbacks of the chemically amplified (CA) organic photosensitive composition, an inorganic photosensitive composition has been researched. The inorganic photosensitive composition is mainly or predominantly utilized for negative tone patterning having resistance against removal by a developer composition due to chemical modification through nonchemical amplification mechanism. The inorganic composition contains an inorganic element having a higher EUV absorption rate than hydrocarbon and thus may secure sensitivity through the nonchemical amplification mechanism and, in addition, is less sensitive about a stochastic effect and thus may have low line edge roughness and the small number of defects.

Inorganic photoresists based on peroxopolyacids of tungsten mixed with tungsten, niobium, titanium, and/or tantalum are radiation-sensitive materials for patterning. These materials are effective or suitable to pattern large pitches for bilayer configuration or arrangement as far ultraviolet (deep UV), X-ray, and electron beam sources.

Utilizing cationic hafnium metal oxide sulfate (HfSOx) materials along with a peroxo complexing agent to image a 15 nm half-pitch (HP) through projection EUV exposure exhibits the highest performance of a non-CA photoresist and has a practicable photospeed near to a requirement for an EUV photoresist. However, the hafnium metal oxide sulfate material having the peroxo complexing agent has a few practical drawbacks. First, these materials are coated in a mixture of corrosive sulfuric acid/hydrogen peroxide and have insufficient or unsuitable shelf-life stability. Second, a structural change of the materials for performance improvement or enhancement as a composite mixture is challenging. Third, development should be performed in a tetramethylammonium hydroxide (TMAH) solution at an extremely high concentration of 25 wt % and/or the like.

Molecules including tin (Sn) have excellent or suitable absorption of extreme ultraviolet rays. As for an organotin polymer among them, alkyl ligands are dissociated by light absorption and/or secondary electrons produced thereby and are crosslinked with adjacent chains through oxo bonds and thus enable the negative tone patterning which may not be removed by an organic developer. This organotin polymer exhibits greatly or substantially improved or enhanced sensitivity as well as maintains a resolution and line edge roughness, but the patterning characteristics should be additionally improved or enhanced for commercial availability.

### SUMMARY

One or more aspects of embodiments of the present disclosure are directed toward a semiconductor photoresist composition capable of implementing a photoresist pattern having excellent or suitable sensitivity and LER characteristics, and suppression of bridge defects (or reduction of a degree or occurrence of bridge defects).

One or more aspects of embodiments of the present disclosure are directed toward a method of forming or providing patterns utilizing the semiconductor photoresist composition.

Additional aspects of embodiments will be set forth in part in the description which follows and, in part, will be apparent from the description or may be learned by practice of the presented embodiments of the disclosure.

A semiconductor photoresist composition according to one or more embodiments includes an organometallic compound represented by Chemical Formula 1 and a solvent.

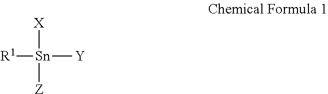

In Chemical Formula 1,
R¹ is selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X, Y, and Z are each independently selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, a substituted or unsubstituted C1 to C30 alkylcarbonyl group, —O-L^{a}-R^{a}, —S-L^{b}-R^{b}, and —O(CO)-L^{c}-R^{c}, at least one selected from among X, Y, and Z is —O-L^{a}-R^{a}, —S-L^{b}-R^{b}, or —O(CO)-L^{c}-R^{c},
L^{a}, L^{b}, and L^{c} are each independently a single bond (e.g., a single covalent bond) or a substituted or unsubstituted C1 to C10 alkylene group,
R^{a}, R^{b}, and R^{c} are each independently —C(R²)═C(R³)(R⁴) or —C≡C(R⁵),
R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group,
R³ and R⁴ are each independently hydrogen, a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
at least one selected from R³ and R⁴ is a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
R⁵ is a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C≡(R⁸),
L¹ and L² are a substituted or unsubstituted C1 to C10 alkylene group, and
R⁶ to R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group.

A method of forming or providing patterns according to one or more embodiments includes forming or providing an etching-objective layer on a substrate, coating the semiconductor photoresist composition as described in one or more embodiments on the etching-objective layer to form or provide a photoresist film, exposing and developing the photoresist film to form or provide a photoresist film having a photoresist pattern formed or provided thereon (e.g., exposing and developing the photoresist film to form a photoresist pattern on the photoresist film), and etching the etching-objective layer utilizing the photoresist pattern as an etching mask.

The semiconductor photoresist composition according to one or more embodiments may provide a photoresist pattern having improved or enhanced sensitivity and LER characteristics and suppressed bridge defects (or a reduced degree or occurrence of bridge defects).

### BRIEF DESCRIPTION OF THE DRAWINGS

The above and other aspects and features of certain embodiments of the present disclosure will become more apparent from the following description taken in conjunction with the accompanying drawings.

FIGS. 1A-1E are cross-sectional views illustrating a method of forming or providing patterns utilizing a semiconductor photoresist composition according to one or more embodiments.

### DETAILED DESCRIPTION

The subject matter of the present disclosure will be described more fully hereinafter with reference to the accompanying drawings, in which embodiments of the present disclosure are shown. As those skilled in the art would realize, the described embodiments may be modified in one or more suitable different ways, all without departing from the spirit or scope of the present disclosure. The drawings and description are to be regarded as illustrative in nature and not restrictive. Like reference numerals designate like elements throughout, and duplicative descriptions thereof may not be provided in the specification.

In order to clearly illustrate the present disclosure, the description and relationships may not be provided, and throughout the disclosure, substantially the same or similar configuration or arrangement elements may be designated by the same reference numerals. Also, because the size and thickness of each configuration or arrangement as illustrated in the drawing may be arbitrarily shown for better understanding and ease of description, embodiments of the present disclosure are not necessarily limited thereto.

In the drawings, the thickness of layers, films, panels, regions, and/or the like may be exaggerated for clarity. In the drawings, the thickness of a part of layers, regions, and/or the like may be exaggerated for convenience of description.

It will be understood that if (e.g., when) an element, such as a layer, a film, a region, or a substrate, is referred to as being “on” another element, it may be directly on the other element or intervening elements may also be present therebetween. In contrast, if (e.g., when) an element is referred to as being “directly on” another element, there are no intervening elements present therebetween.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,” “utilizing,” and “utilized,” respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As used herein, “combination thereof” may refer to a mixture, a stack, a composite, a copolymer, an alloy, a blend, a reaction product, and/or the like of constituents.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within +30%, +20%, +10%, or +5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

As used herein, “substituted” refers to replacement of a hydrogen atom by deuterium, a halogen, a hydroxy group, a carboxyl group, a thiol group, a cyano group, a nitro group, —NRR′ (wherein, R and R′ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ are each independently hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a substituted or unsubstituted C1 to C30 alkyl group, a substituted or unsubstituted C1 to C10 haloalkyl group, a substituted or unsubstituted C1 to C10 alkylsilyl group, a substituted or unsubstituted C3 to C30 cycloalkyl group, a substituted or unsubstituted C6 to C30 aryl group, a substituted or unsubstituted C1 to C20 alkoxy group, a substituted or unsubstituted C1 to C20 sulfide group, or a combination thereof. “Unsubstituted” refers to non-replacement of a hydrogen atom by another substituent and remaining of the hydrogen atom.

As used herein, if (e.g., when) a definition is not otherwise provided, “alkyl group” refers to a linear or branched aliphatic hydrocarbon group. The alkyl group may be “saturated alkyl group” without any double bond (e.g., a carbon-carbon double bond) or triple bond (e.g., a carbon-carbon triple bond).

The alkyl group may be a C1 to C8 alkyl group. For example, the alkyl group may be a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, “cycloalkyl group” refers to a monovalent cyclic aliphatic hydrocarbon group.

The cycloalkyl group may be a C3 to C8 cycloalkyl group, for example, a C3 to C7 cycloalkyl group, a C3 to C6 cycloalkyl group, a C3 to C5 cycloalkyl group, or a C3 to C4 cycloalkyl group. The cycloalkyl group may be a cyclopropyl group, a cyclobutyl group, a cyclopentyl group, or a cyclohexyl group, but embodiments of the present disclosure are not limited thereto.

In the present specification, “aliphatic unsaturated organic group” refers to a hydrocarbon group including a bond in which the bond between the carbon and carbon atom in the molecule is a double bond (e.g., a carbon-carbon double bond), a triple bond (e.g., a carbon-carbon triple bond), or a combination thereof.

The aliphatic unsaturated organic group may be a C2 to C8 aliphatic unsaturated organic group. For example, the aliphatic unsaturated organic group may be a C2 to C7 aliphatic unsaturated organic group, a C2 to C6 aliphatic unsaturated organic group, a C2 to C5 aliphatic unsaturated organic group, or a C2 to C4 aliphatic unsaturated organic group. For example, the C2 to C4 aliphatic unsaturated organic group may be a vinyl group, an ethynyl group, an allyl group, a 1-propenyl group, a 1-methyl-1-propenyl group, a 2-propenyl group, a 2-methyl-2-propenyl group, a 1-propynyl group, a 1-methyl-1-propynyl group, a 2-propynyl group, a 2-methyl-2-propynyl group, a 1-butenyl group, a 2-butenyl group, a 3-butenyl group, a 1-butynyl group, a 2-butynyl group, or a 3-butynyl group.

As used herein, “aryl group” refers to a substituent in which all atoms in the cyclic substituent have a p-orbital, and these p-orbitals are conjugated and may include a monocyclic or fused ring polycyclic functional group (e.g., rings sharing adjacent pairs of carbon atoms).

As used herein, “heteroaryl group” may refer to an aryl group including at least one heteroatom selected from among nitrogen (N), oxygen (O), sulfur(S), phosphorus (P), and silicon (Si). Two or more heteroaryl groups are linked by a sigma bond directly, or if (e.g., when) the heteroaryl group includes two or more rings, the two or more rings may be fused. If (e.g., when) the heteroaryl group is a fused ring, each ring may include one to three heteroatoms.

As used herein, unless otherwise defined, “alkenyl group” refers to an aliphatic unsaturated alkenyl group including at least one double bond (e.g., a carbon-carbon double bond) as a linear or branched aliphatic hydrocarbon group.

As used herein, unless otherwise defined, “alkynyl group” refers to an aliphatic unsaturated alkynyl group including at least one triple bond (e.g., a carbon-carbon triple bond) as a linear or branched aliphatic hydrocarbon group.

Hereinafter, a semiconductor photoresist composition according to one or more embodiments is described in more detail.

A semiconductor photoresist composition according to one or more embodiments may include an organometallic compound represented by Chemical Formula 1 and a solvent.

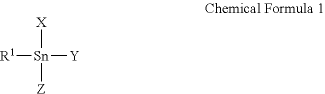

In Chemical Formula 1,
R¹ may be selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X, Y, and Z may each independently be selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, a substituted or unsubstituted C1 to C30 alkylcarbonyl group, —O-L^{a}-R^{a}, —S-L^{b}-R^{b}, and —O(CO)-L^{c}-R^{c},
at least one selected from among X, Y, and Z may be —O-L^{a}-R^{a}, —S-L^{b}-R^{b}, or —O(CO)-L^{c}-R^{c},
L^{a}, L^{b}, and L^{c} may each independently be a single bond (e.g., a single covalent bond) or a substituted or unsubstituted C1 to C10 alkylene group,
R^{a}, R^{b}, and R^{c} may each independently be —C(R²)═C(R³)(R⁴) or —C≡C(R⁵),
R² may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group,
R³ and R⁴ may each independently be hydrogen, a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
at least one selected from R³ and R⁴ may be a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
R⁵ may be a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
L¹ and L² may be a substituted or unsubstituted C1 to C10 alkylene group, and
R⁶ to R⁸ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group.

The organometallic compound according to the present disclosure may further improve or enhance sensitivity and LER characteristics by enabling crosslinking between ligands and helping in the formation of metal clusters due to an unsaturated bond in a hydrolyzable functional group.

For example, because the unsaturated bond is present inside the hydrolyzable ligand rather than at the terminal end thereof, the reactivity may be lowered or reduced, thereby suppressing or reducing the occurrence of bridge defects after pattern formation.

In one or more embodiments, the hydrolyzable ligand may include a triple bond (e.g., a carbon-carbon triple bond).

For example, R^{a}, R^{b}, and R^{c} may be —C≡C(R⁵).

The sensitivity may be further improved or enhanced if (e.g., when) the hydrolyzable ligand includes a triple bond (e.g., a carbon-carbon triple bond).

In one or more embodiments, X, Y, and Z may each independently be —O-L^{a}-R^{a}, —S-L^{b}-R^{b}, or —O(CO)-L^{c}-R^{c}.

In one or more embodiments, X, Y, and Z may be the same each other.

For example, R¹ may be selected from among a substituted or unsubstituted C1 to C10 alkyl group, a substituted or unsubstituted C2 to C20 heteroalkyl group, a substituted or unsubstituted C3 to C12 cycloalkyl group, a substituted or unsubstituted C2 to C20 heterocycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C2 to C20 heteroaryl group, a substituted or unsubstituted C7 to C20 arylalkyl group, a substituted or unsubstituted C4 to C20 heteroarylalkyl group, and a substituted or unsubstituted C1 to C20 alkylcarbonyl group.

For example, R¹ may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 1-methylpropyl group, a substituted or unsubstituted 1,1-dimethylpropyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, or a substituted or unsubstituted benzyl group.

For example, R² may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group,
R³ and R⁴ may each independently be hydrogen, a substituted or unsubstituted C1 to C10 alkyl group, a substituted or unsubstituted C3 to C10 cycloalkyl group, a substituted or unsubstituted C6 to C20 aryl group, -L¹-C═C(R⁶)(R⁷), or -L²-C≡C(R⁸),
at least one selected from R³ and R⁴ may be a substituted or unsubstituted C1 to C10 alkyl group, a substituted or unsubstituted C3 to C10 cycloalkyl group, a substituted or unsubstituted C6 to C20 aryl group, -L¹-C═C(R⁶)(R⁷), or -L²-C≡C(R⁸),
R⁵ may be a substituted or unsubstituted C1 to C10 alkyl group, a substituted or unsubstituted C3 to C10 cycloalkyl group, a substituted or unsubstituted C6 to C20 aryl group, -L¹-C═C(R⁶)(R⁷), or -L²-C≡C(R⁸),
L¹ and L² may be a substituted or unsubstituted C1 to C6 alkylene group,
R⁶ to R⁸ may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group.

In one or more embodiments, the organometallic compound represented by Chemical Formula 1 may be selected from among the compounds listed in Group 1.

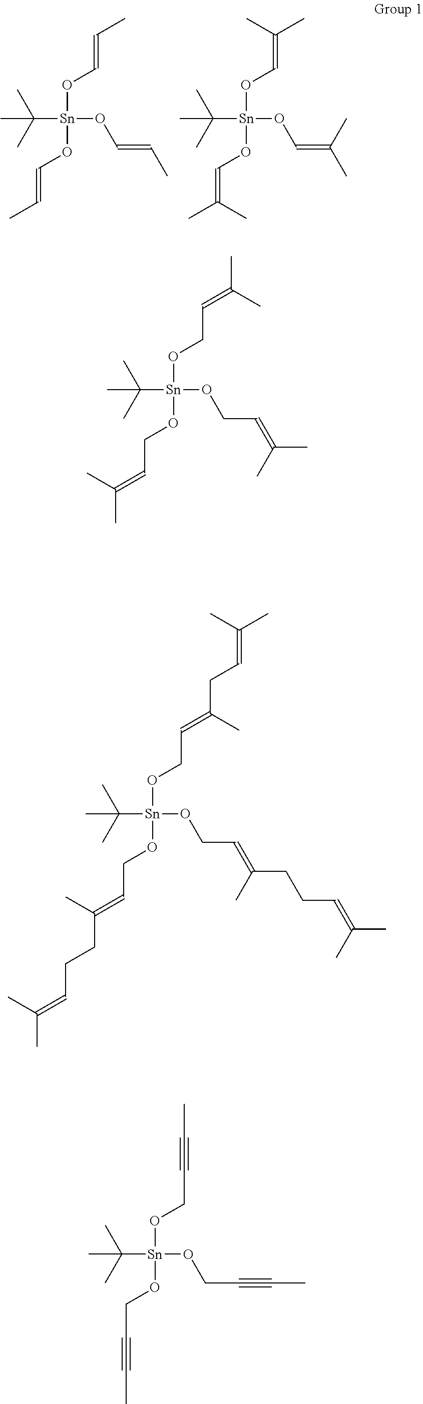

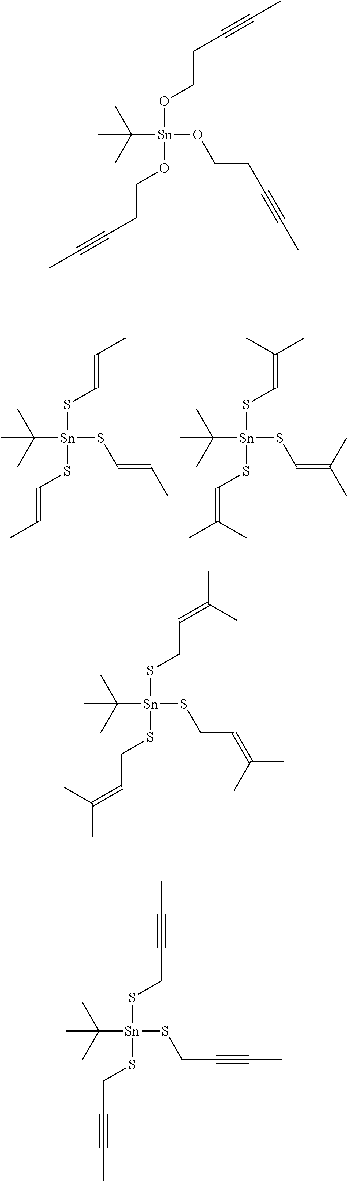

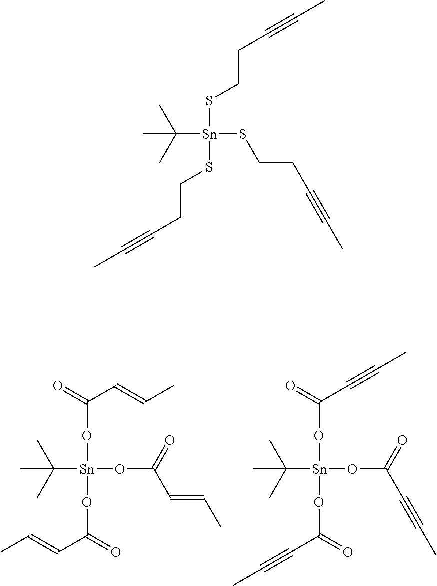 [SMILES: CC#CCC[S][Sn]([S]CCC#CC)([S]CCC#CC)[C](C)(C)C ; C/C=C/C(=O)[O][Sn]([O]C(=O)/C=C/C)([O]C(=O)/C=C/C)[C](C)(C)C ; CC#CC(=O)[O][Sn]([O]C(=O)C#CC)([O]C(=O)C#CC)[C](C)(C)C]

The organometallic compound represented by Chemical Formula 1 may strongly absorb extreme ultraviolet light at 13.5 nm and thus have excellent or suitable sensitivity to light having high energy.

In the semiconductor photoresist composition according to one or more embodiments, the organometallic compound represented by Chemical Formula 1 may be in an amount of about 0.5 wt % to about 30 wt %, for example, about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, for example, about 1 wt % to about 5 wt %, based on 100 wt % of the semiconductor photoresist composition, but embodiments of the present disclosure are not limited thereto. If (e.g., when) the organometallic compound is in the content (e.g., amount) within the foregoing ranges, the storage stability and etch resistance of the semiconductor photoresist composition may be improved or enhanced, and the resolution characteristics may be improved or enhanced.

The semiconductor photoresist composition according to one or more embodiments may have excellent or suitable sensitivity and pattern-forming properties by including the organometallic compound as described in one or more embodiments.

The solvent in the semiconductor photoresist composition according to one or more embodiments may be an organic solvent, and may be, for example, aromatic compounds (e.g., xylene, toluene, and/or the like), alcohols (e.g., 4-methyl-2-pentanol, 4-methyl-2-propanol, 1-butanol, methanol, isopropyl alcohol, 1-propanol, and/or the like), ethers (e.g., anisole, tetrahydrofuran, and/or the like), esters (e.g., n-butyl acetate, propylene glycol monomethyl ether acetate, ethyl acetate, ethyl lactate, and/or the like), ketones (e.g., methyl ethyl ketone, 2-heptanone, and/or the like), or a mixture thereof, but embodiments of the present disclosure are not limited thereto.

The semiconductor photoresist composition according to one or more embodiments may further include a resin in addition to the organometallic compound as described in one or more embodiments and the solvent as described in one or more embodiments.

The resin may be a phenol-based resin including at least one selected from among the aromatic moieties listed in Group 2.

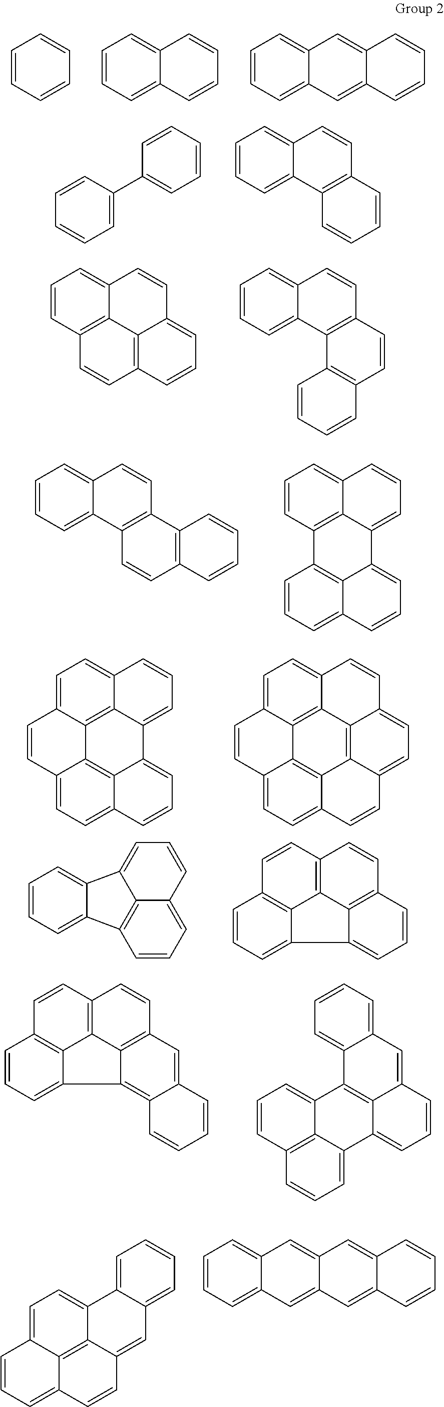

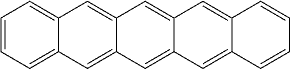 [SMILES: c1ccc2cc3cc4cc5ccccc5cc4cc3cc2c1]

The resin may have a weight average molecular weight (Mw) in a range of about 500 g/mol to about 20,000 g/mol.

The resin may be in an amount in a range of about 0.1 wt % to about 50 wt % based on a total amount (e.g., based on 100 wt %) of the semiconductor photoresist composition.

If (e.g., when) the resin is in the foregoing content (e.g., amount) range, it may have excellent or suitable etch resistance and heat resistance.

In one or more embodiments, the semiconductor photoresist composition may be composed of the organometallic compound, solvent, and resin as described in one or more embodiments. However, the semiconductor photoresist composition according to one or more embodiments may further include additives as needed or desired. Examples of the additives may be a surfactant, a crosslinking agent, a leveling agent, an organic acid, a quencher, or a combination thereof.

The surfactant may include, for example, an alkyl benzene sulfonate salt, an alkyl pyridinium salt, polyethylene glycol, a quaternary ammonium salt, or a combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. It may be a crosslinking agent having at least two crosslinking forming substituents, for example, a compound, such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be utilized to improve or enhance coating flatness during printing and may be a leveling agent that is generally available or generally used.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a combination thereof.

Each use amount of the additives may be controlled or selected depending on desired properties.

In one or more embodiments, the semiconductor photoresist composition may further include a silane coupling agent as an adherence enhancer in order to improve or enhance a close-contacting force with the substrate (e.g., in order to improve or enhance adherence of the semiconductor photoresist composition to the substrate). The silane coupling agent may be, for example, a silane compound including a carbon-carbon unsaturated bond, such as vinyltrimethoxysilane, vinyl triethoxysilane, vinyl trichlorosilane, vinyl tris(β-methoxyethoxy) silane, 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane, trimethoxy [3-(phenylamino)propyl]silane, and/or the like, but embodiments of the present disclosure are not limited thereto.

The semiconductor photoresist composition may be formed into a pattern having a high aspect ratio without a collapse. Accordingly, in order to form or provide a fine pattern having a width in a range of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, for example, about 5 nm to about 20 nm, or for example, about 5 nm to about 10 nm, the semiconductor photoresist composition may be utilized for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be utilized to realize or provide extreme ultraviolet lithography using an EUV light source of a wavelength of about 13.5 nm.

According to one or more embodiments, a method of forming or providing patterns utilizing the semiconductor photoresist composition as described in one or more embodiments is provided. For example, the manufactured pattern may be a photoresist pattern.

A method of forming or providing patterns according to one or more embodiments may include forming or providing an etching-objective layer on a substrate, coating the semiconductor photoresist composition as described in one or more embodiments on the etching-objective layer to form or provide a photoresist film, exposing and developing the photoresist film to form or provide a photoresist film having a photoresist pattern formed or provided thereon (e.g., exposing and developing the photoresist film to form or provide a photoresist pattern on the photoresist film), and etching the etching-objective layer utilizing the photoresist pattern as an etching mask.

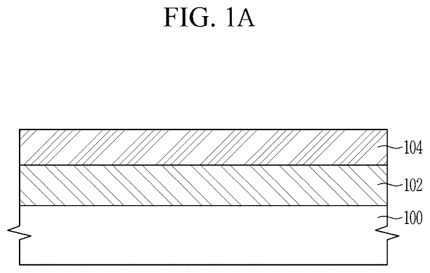

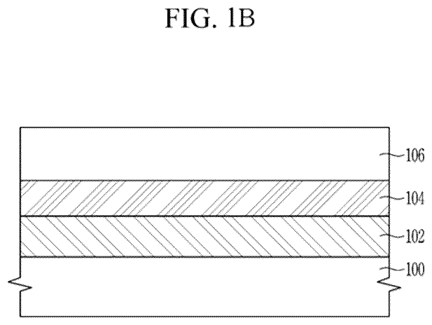

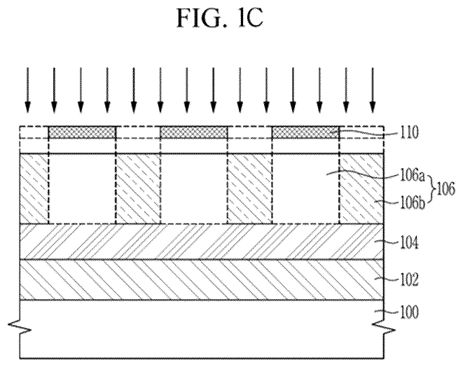

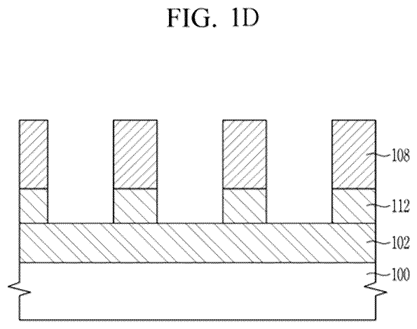

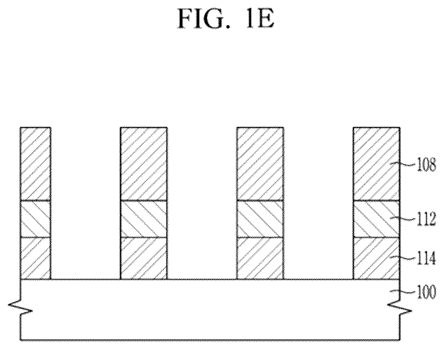

Hereinafter, a method of forming or providing patterns utilizing the semiconductor photoresist composition is described in more detail referring to FIGS. 1A-1E. FIGS. 1A-1E are cross-sectional views illustrating a method of forming or providing patterns utilizing a semiconductor photoresist composition according to one or more embodiments.

Referring to FIG. 1A, an object to etch may be prepared. The object to etch may be a thin film 102 formed or provided on a semiconductor substrate 100. Hereinafter, the object to etch may be limited to the thin film 102. A surface of the thin film 102 may be washed to remove impurities and/or the like remaining thereon. The thin film 102 may be, for example, a silicon nitride layer, a polysilicon layer, or a silicon oxide layer.

Subsequently, the resist underlayer composition to form or provide a resist underlayer 104 may be spin-coated on the surface of the washed thin film 102. However, embodiments of the present disclosure are not limited thereto, and one or more suitable coating methods that are generally available, for example, a spray coating, a dip coating, a knife edge coating, a printing method, for example, an inkjet printing and a screen printing, and/or the like, may be used.

The coating process of the resist underlayer may not be provided, and hereinafter, a process including a coating of the resist underlayer is described in more detail.

Then, the coated composition may be dried and baked to form or provide a resist underlayer 104 on the thin film 102. The baking may be performed at about 100° C. to about 500° C., for example, about 100° C. to about 300° C.

The resist underlayer 104 may be formed or provided between the substrate 100 and a photoresist film 106 and thus may prevent non-uniformity and pattern formability of a photoresist line width (or reduce a degree or occurrence of non-uniformity and pattern formability of a photoresist line width) if (e.g., when) a ray reflected from on the interface between the substrate 100 and the photoresist film 106 or a hardmask between layers is scattered into an unintended photoresist region.

Referring to FIG. 1B, the photoresist film 106 may be formed or provided by coating the semiconductor photoresist composition as described in one or more embodiments on the resist underlayer 104. The photoresist film 106 may be obtained by coating the semiconductor photoresist composition as described in one or more embodiments on the thin film 102 formed or provided on the substrate 100 and then, curing it through a heat treatment.

For example, the formation of a pattern by utilizing the semiconductor photoresist composition may include coating the semiconductor photoresist composition on the substrate 100 having the thin film 102 through spin coating, slit coating, inkjet printing, and/or the like and then, drying it to form or provide the photoresist film 106.

The semiconductor photoresist composition has already been illustrated in more detail and may not be illustrated again.

Subsequently, a substrate 100 having the photoresist film 106 may be subjected to a first baking process. The first baking process may be performed at about 80° C. to about 120° C.

Referring to FIG. 1C, the photoresist film 106 may be selectively exposed utilizing a patterned mask 110.

For example, the exposure may use an activation radiation with light having a high energy wavelength, such as extreme ultraviolet (EUV; a wavelength of about 13.5 nm) and/or the like, and other sources, such as an electron beam (e-beam) and/or the like, as well as light having a low energy wavelength, such as an i-line (a wavelength of about 365 nm), a KrF excimer laser (a wavelength of about 248 nm), an ArF excimer laser (a wavelength of about 193 nm), and/or the like.

For example, light for the exposure according to one or more embodiments may be light having a short wavelength in a range of about 5 nm to about 150 nm and a high energy wavelength, for example, extreme ultraviolet (EUV; a wavelength of 13.5 nm) and/or the like, and other sources, such as an electron beam (e-beam) and/or the like.

The exposed region 106b of the photoresist film 106 may have a different solubility from the unexposed region 106a of the photoresist film 106 by forming or providing a polymer by a crosslinking reaction, such as condensation between organometallic compounds.

Subsequently, the substrate 100 may be subjected to a second baking process. The second baking process may be performed at a temperature of about 90° C. to about 200° C. The exposed region 106b of the photoresist film 106 may become easily indissoluble regarding a developer due to the second baking process.

In FIG. 1D, the unexposed region 106a of the photoresist film may be dissolved and removed utilizing the developer to form or provide a photoresist pattern 108. For example, the unexposed region 106a of the photoresist film may be dissolved and removed by utilizing an organic solvent, such as 2-heptanone and/or the like, to complete the photoresist pattern 108 corresponding to the negative tone image.

As described in one or more embodiments, a developer utilized in a method of forming or providing patterns according to one or more embodiments may be an organic solvent. The organic solvent utilized in the method of forming or providing patterns according to one or more embodiments may be, for example, ketones, such as methylethylketone, acetone, cyclohexanone, 2-heptanone, and/or the like, alcohols, such as 4-methyl-2-propanol, 1-butanol, isopropanol, 1-propanol, methanol, and/or the like, esters, such as propylene glycol monomethyl ether acetate, ethyl acetate, ethyl lactate, n-butyl acetate, butyrolactone, and/or the like, aromatic compounds, such as benzene, xylene, toluene, and/or the like, or a combination thereof.

However, the photoresist pattern according to one or more embodiments is not necessarily limited to the negative tone image but may be formed or provided to have a positive tone image. Here, a developer utilized to form or provide the positive tone image may be a quaternary ammonium hydroxide composition, such as tetraethylammonium hydroxide, tetrapropylammonium hydroxide, tetrabutylammonium hydroxide, or a combination thereof.

As described in one or more embodiments, exposure to light having a high energy wavelength, such as extreme ultraviolet (EUV; a wavelength of 13.5 nm) and/or the like, and other sources, such as an electron beam (e-beam) and/or the like, as well as light having low energy wavelength, such as i-line (wavelength of about 365 nm), KrF excimer laser (wavelength of about 248 nm), ArF excimer laser (wavelength of about 193 nm), and/or the like, may provide a photoresist pattern 108 having a width of a thickness in a range of about 5 nm to about 100 nm. For example, the photoresist pattern 108 may have a width of a thickness in a range of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

In one or more embodiments, the photoresist pattern 108 may have a pitch having a half-pitch of less than or equal to about 50 nm, for example, less than or equal to about 40 nm, for example, less than or equal to about 30 nm, for example, less than or equal to about 20 nm, or, for example, less than or equal to about 10 nm, and a line width roughness of less than or equal to about 5 nm, less than or equal to about 3 nm, less than or equal to about 2 nm, or less than or equal to about 1 nm.

According to one or more embodiments, a photoresist film manufactured by the method of forming or providing patterns as described in one or more embodiments may be provided.

Subsequently, the resist underlayer 104 may be etched utilizing the photoresist pattern 108 formed or provided on the photoresist film as an etching mask. Through this etching process, an organic film pattern 112 may be formed or provided. The organic film pattern 112 may also have a width corresponding to a width of the photoresist pattern 108.

Referring to FIG. 1E, the exposed thin film 102 may be etched by applying the photoresist pattern 108 as an etching mask. As a result, the thin film may be formed or provided as a thin film pattern 114.

The etching of the thin film 102 may be, for example, dry etching using an etching gas, and the etching gas may be, for example, CHF₃, CF₄, Cl₂, BCl₃ and a mixed gas thereof.

In the exposure process, the thin film pattern 114 formed or provided by utilizing the photoresist pattern 108 formed or provided through the exposure process performed by using an EUV light source may have a width corresponding to a width of the photoresist pattern 108. For example, the thin film pattern 114 may have a width in a range of about 5 nm to about 100 nm which is equal to a width of the photoresist pattern 108. For example, the thin film pattern 114 formed or provided by utilizing the photoresist pattern 108 formed or provided through the exposure process performed by using an EUV light source may have a width in a range of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and, for example, a width of less than or equal to about 20 nm, like a width of the photoresist pattern 108.

Hereinafter, one or more embodiments of the present disclosure will be described in more detail through examples of the preparation of the semiconductor photoresist composition as described in one or more embodiments. However, embodiments of the present disclosure are not restricted by the following examples.

### EXAMPLES

### Synthesis of Organometallic Compounds

### Synthesis Example 1

t-ButylSnPh₃ (40.7 g) and 2-butyn-1-ol (300 g) were added in a 100 mL round-bottom flask and heated under reflux for 24 hours. Unreacted substances were removed under reduced pressure to obtain a compound represented by Chemical Formula 2.

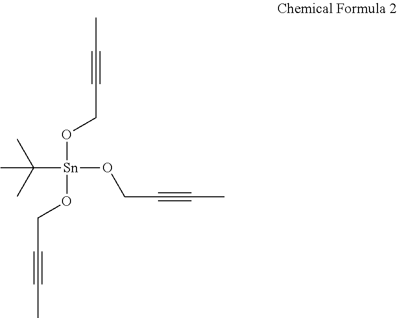 [SMILES: CC#CC[O][Sn]([O]CC#CC)([O]CC#CC)[C](C)(C)C]

### Synthesis Example 2

A compound represented by Chemical Formula 3 was obtained by performing substantially the same procedure as in Synthesis Example 1, except that 3-pentyn-1-ol (300 g) was used instead of 2-butyn-1-ol.

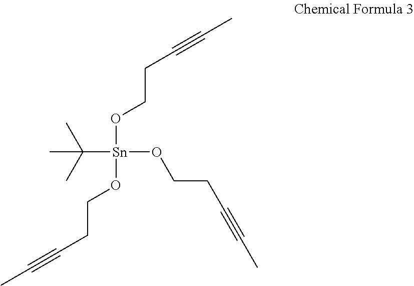 [SMILES: CC#CCC[O][Sn]([O]CCC#CC)([O]CCC#CC)[C](C)(C)C]

### Synthesis Example 3

A compound represented by Chemical Formula 4 was obtained by performing substantially the same procedure as in Synthesis Example 1, except that 3,6-dimethyl-2,5-heptadien-1-ol (300 g) was used instead of 2-butyn-1-ol.

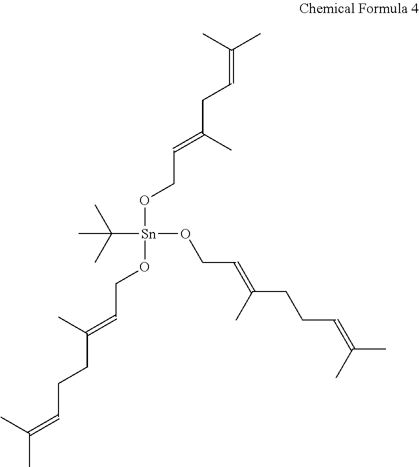 [SMILES: CC(C)=CCC/C(C)=C/C[O][Sn]([O]C/C=C(\C)CC=C(C)C)([O]C/C=C(\C)CCC=C(C)C)[C](C)(C)C]

### Synthesis Example 4

A compound represented by Chemical Formula 5 was obtained by performing substantially the same procedure as in Synthesis Example 1, except that 1-propene-1-thiol (300 g) was used instead of 2-butyn-1-ol.

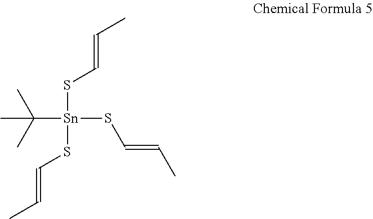 [SMILES: C/C=C/[S][Sn]([S]/C=C/C)([S]/C=C/C)[C](C)(C)C]

### Synthesis Example 5

A compound represented by Chemical Formula 6 was obtained by performing substantially the same procedure as in Synthesis Example 1, except that crotonic acid (300 g) was used instead of 2-butyn-1-ol.

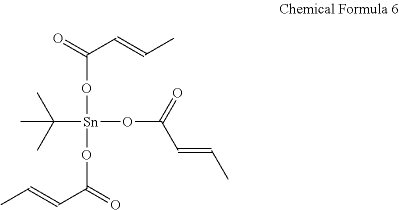 [SMILES: C/C=C/C(=O)[O][Sn]([O]C(=O)/C=C/C)([O]C(=O)/C=C/C)[C](C)(C)C]

### Comparative Synthesis Example 1

In a 250 mL two-neck round-bottomed flask, Ph₃SnCl (20 g, 51.9 mmol) was dissolved in 70 mL of THF and then, cooled to 0° C. in an ice bath. Subsequently, a 1 M butyl magnesium chloride (BuMgCl) THF solution (62.3 mmol) was slowly added thereto in a dropwise fashion. When the dropwise addition was completed, the mixture was stirred at room temperature for 12 hours to obtain a compound represented by Chemical Formula A-1.

The compound represented by Chemical Formula A-1 (10 g, 24.6 mmol) was dissolved in 50 mL of CH₂Cl₂, a 2 M HCl diethyl ether solution (3 equivalent, 73.7 mmol) was slowly added thereto in a dropwise fashion at −78° C. for 30 minutes. Subsequently, after stirring the mixture at room temperature for 12 hours, the solvent was concentrated and vacuum-distilled to obtain a compound represented by Chemical Formula A-2.

The compound represented by Chemical Formula A-2 (5 g, 17.7 mmol) was dissolved in 50 mL of THF and then, cooled to 0° C. in the ice bath. Subsequently, a 2 M allyl magnesium chloride (allylMgCl) THE solution (58 mmol) was slowly added thereto in a dropwise fashion. When the dropwise addition was completed, the mixture was stirred at room temperature for 12 hours to obtain a compound represented by Chemical Formula 7.

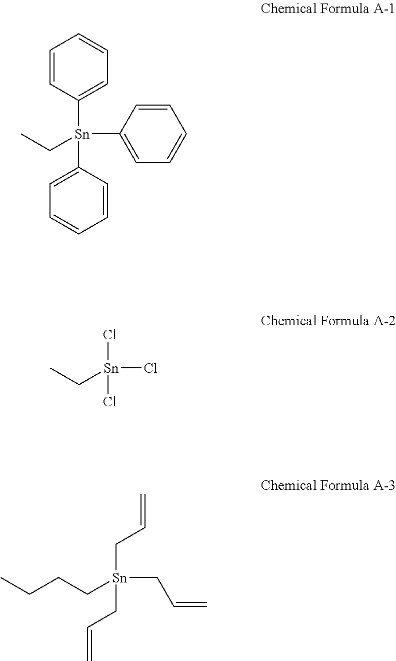

### Comparative Synthesis Example 2

A compound represented by Chemical Formula 8 was obtained in substantially the same manner as in Synthesis Example 1 except that 300 g of 3-butyn-1-ol was used instead of the 2-butyn-1-ol.

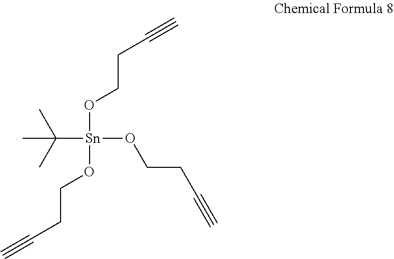 [SMILES: C#CCC[O][Sn]([O]CCC#C)([O]CCC#C)[C](C)(C)C]

### Comparative Synthesis Example 3

A compound represented by Chemical Formula 9 was obtained in substantially the same manner as in Synthesis Example 1 except that 300 g of 3-butyn-1-thiol was used instead of the 2-butyn-1-ol.

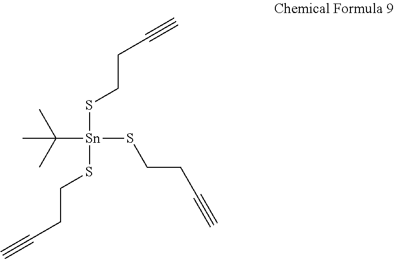 [SMILES: C#CCC[S][Sn]([S]CCC#C)([S]CCC#C)[C](C)(C)C]

### Comparative Synthesis Example 4

A compound represented by Chemical Formula 10 was obtained in substantially the same manner as in Synthesis Example 1 except that 300 g of 3-butenoic acid was used instead of the 2-butyn-1-ol.

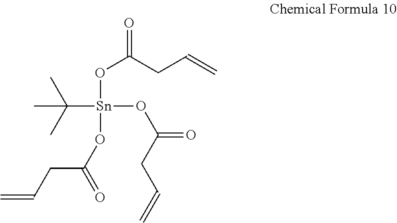 [SMILES: C=CCC(=O)[O][Sn]([O]C(=O)CC=C)([O]C(=O)CC=C)[C](C)(C)C]

### Preparation of Semiconductor Photoresist Compositions

### Examples 1 to 5 and Comparative Examples 1 to 4

The organometallic compounds obtained in Synthetic Examples 1 to 5 and Comparative Synthetic Examples 1 to 4 were each dissolved in 3 wt % of propylene glycol monomethyl ether acetate (PGMEA) and filtered through a 0.1 μm polytetrafluoroethylene (PTFE) syringe filter to prepare photoresist compositions.

### Evaluation 1: Evaluation of Sensitivity and Line Edge Roughness (LER)

Each of the photoresist compositions according to Examples and Comparative Examples was spin-coated for 30 seconds at 1500 rpm, respectively, on a 200 mm circular silicon wafer whose surface was deposited with hexamethyldisilazane (HMDS), and baked at 110° C. for 60 seconds. After application, it was baked (post-apply bake, PAB) and then left at room temperature (23±2° C.) for 30 seconds.

Then, a linear array of 50 circular pads with a diameter of 500 μm was projected onto the wafer coated with the photoresist composition using EUV light (Lawrence Berkeley National Laboratory Micro Exposure Tool, MET). Here, pad exposure time was adjusted to ensure that the EUV light in an increased dose was applied to each pad.

Then, the resist and the substrate were baked at 160° C. for 120 seconds on a hot plate after the exposure. The baked film was developed in a PGMEA solvent to form a negative tone image. Finally, the obtained film was baked again at 150° C. for 2 minutes on the hot plate, completing the process.

The remaining resist thickness of the exposed pad was measured using an ellipsometer. The remaining thickness was measured for each exposure dose and then, graphed as a function to the exposure doses to measure sensitivity, and LER was measured from a field emission scanning electron microscope (FE-SEM) image to evaluate line edge roughness, and then, the results are shown in Table 1.

### Evaluation 2: Evaluation of Defects

On a 12-inch silicon substrate, a lower SiON film/a spin-on carbon film/an upper SiON film in order were formed. On the upper SiON film, each of the photoresist compositions according to Examples and Comparative Examples was used to form a 1:1 line/space photoresist pattern with a pitch of 36 nm in an EUV lithography method. The photoresist pattern was transferred to the lower SiON film through dry etching using a plasma. Then, all defects including bridge defects between the line patterns were inspected in a bright field with a defect analysis equipment using a DUV laser. The inspected defects were classified by using SEM and then, shown as the number of the classified defects per unit area (ea/cm²).

Herein, when the number of SLO (Single Line Open) defects was converted to 100, if the number of defects was less than or equal to 80%, ‘∘’ was given, and if the number of defects was greater than 80%, ‘X’ was given.

TABLE 1

| | Organometallic | LER | Sensitivity | Defect |
|---|---|---|---|---|
| | compound | (nm) | (mJ/cm²) | evaluation |
| Example 1 | Chemical Formula 2 | 2.7 | 30.6 | ◯ |
| Example 2 | Chemical Formula 3 | 2.9 | 31.5 | ◯ |
| Example 3 | Chemical Formula 4 | 2.8 | 33.4 | ◯ |
| Example 4 | Chemical Formula 5 | 2.9 | 33.4 | ◯ |
| Example 5 | Chemical Formula 6 | 2.9 | 32.4 | ◯ |
| Comparative | Chemical Formula 7 | 4.2 | 50.0 | X |
| Example 1 | | | | |
| Comparative | Chemical Formula 8 | 3.7 | 62.0 | X |
| Example 2 | | | | |
| Comparative | Chemical Formula 9 | 4.0 | 55.0 | X |
| Example 3 | | | | |
| Comparative | Chemical Formula 10 | 3.9 | 58.0 | X |
| Example 4 | | | | |

From the results in Table 1, the patterns formed utilizing the semiconductor photoresist compositions according to Examples 1 to 5 exhibited superior sensitivity, LER, and resolution characteristics compared to Comparative Examples 1 to 4.

Hereinbefore, certain embodiments of the present disclosure have been described and illustrated, however, it should be apparent to a person having ordinary skill in the art that the present disclosure is not limited to the embodiments as described and may be suitably modified and transformed without departing from the spirit and scope of the present disclosure. Accordingly, the modified or transformed embodiments as such may not be understood separately from the technical ideas and aspects of one or more embodiments of the present disclosure, and the modified embodiments may be within the scope of the appended claims and equivalents thereof of the present disclosure.

Reference Numerals

| | |
|---|---|
| 100: substrate | 102: thin film |
| 104: resist underlayer | 106: photoresist film |
| 106a: unexposed region | 106b: exposed region |
| 108: photoresist pattern | 112: organic film pattern |
| 110: patterned mask | 114: thin film pattern |

What is claimed is:

1. A semiconductor photoresist composition, comprising:
an organometallic compound represented by Chemical Formula 1; and
a solvent: 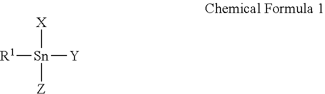
wherein, in Chemical Formula 1,
R¹ is selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, and a substituted or unsubstituted C1 to C30 alkylcarbonyl group,
X, Y, and Z are each independently selected from among a substituted or unsubstituted C1 to C20 alkyl group, a substituted or unsubstituted C2 to C30 heteroalkyl group, a substituted or unsubstituted C3 to C20 cycloalkyl group, a substituted or unsubstituted C2 to C30 heterocycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C2 to C30 heteroaryl group, a substituted or unsubstituted C7 to C30 arylalkyl group, a substituted or unsubstituted C4 to C30 heteroarylalkyl group, a substituted or unsubstituted C1 to C30 alkylcarbonyl group, —O-L^{a}-R^{a}, —S-L^{b}-R^{b}, and —O(CO)-L^{c}-R^{c},
at least one selected from among X, Y, and Z is —O-L^{a}-R^{a}, —S-L^{b}-R^{b}, or —O(CO)-L^{c}-R^{c},
L^{a}, L^{b}, and Le are each independently a single bond or a substituted or unsubstituted C1 to C10 alkylene group,
R^{a}, R^{b}, and R^{o} are each independently —C(R²)═C(R³)(R⁴) or —C≡C(R⁵),
R² is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group,
R³ and R⁴ are each independently hydrogen, a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
at least one selected from R³ and R⁴ is a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
R⁵ is a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
L¹ and L² are a substituted or unsubstituted C1 to C10 alkylene group, and
R⁶ to R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group.

2. The semiconductor photoresist composition as claimed in claim 1, wherein:
R^{a}, R^{b}, and R^{c} are —C≡C(R⁵),
R⁵ is a substituted or unsubstituted C1 to C20 alkyl group, a substituted or unsubstituted C3 to C20 cycloalkyl group, a substituted or unsubstituted C6 to C30 aryl group, -L¹-C═C(R⁶)(R⁷), or -L²-C≡C(R⁸),
L¹ and L² are a substituted or unsubstituted C1 to C10 alkylene group, and
R⁶ to R⁸ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group.

3. The semiconductor photoresist composition as claimed in claim 1, wherein:
X, Y, and Z are each independently —O-L^{a}-R^{a}, —S-L^{b}-R^{b}, or —O(CO)-L^{c}-R^{c}.

4. The semiconductor photoresist composition as claimed in claim 3, wherein:
X, Y, and Z are the same each other.

5. The semiconductor photoresist composition as claimed in claim 1, wherein:
R¹ is selected from among a substituted or unsubstituted C1 to C10 alkyl group, a substituted or unsubstituted C2 to C20 heteroalkyl group, a substituted or unsubstituted C3 to C12 cycloalkyl group, a substituted or unsubstituted C2 to C20 heterocycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C2 to C20 heteroaryl group, a substituted or unsubstituted C7 to C20 arylalkyl group, a substituted or unsubstituted C4 to C20 heteroarylalkyl group, and a substituted or unsubstituted C1 to C20 alkylcarbonyl group.

6. The semiconductor photoresist composition as claimed in claim 1, wherein:
R¹ is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 1-methylpropyl group, a substituted or unsubstituted 1,1-dimethylpropyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, or a substituted or unsubstituted benzyl group.

7. The semiconductor photoresist composition as claimed in claim 1, wherein:
R² is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group,
R³ and R⁴ are each independently hydrogen, a substituted or unsubstituted C1 to C10 alkyl group, a substituted or unsubstituted C3 to C10 cycloalkyl group, a substituted or unsubstituted C6 to C20 aryl group, -L¹-C═C(R⁶)(R⁷), or -L²-C≡C(R⁸),
at least one selected from R³ and R⁴ is a substituted or unsubstituted C1 to C10 alkyl group, a substituted or unsubstituted C3 to C10 cycloalkyl group, a substituted or unsubstituted C6 to C20 aryl group, -L¹-C═C(R⁶)(R⁷), or -L²-C≡C(R⁸),
R⁵ is a substituted or unsubstituted C1 to C10 alkyl group, a substituted or unsubstituted C3 to C10 cycloalkyl group, a substituted or unsubstituted C6 to C20 aryl group, -L¹-C═C(R⁶)(R⁷), or -L²-C≡C(R⁸),
L¹ and L² are a substituted or unsubstituted C1 to C6 alkylene group, and
R⁶ to R⁸ are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group.

8. The semiconductor photoresist composition as claimed in claim 1, wherein:
R² is hydrogen, a substituted or unsubstituted C1 to C10 alkyl group, a substituted or unsubstituted C2 to C10 alkenyl group, or a substituted or unsubstituted C2 to C10 alkynyl group,
R³ and R⁴ are each independently hydrogen, a substituted or unsubstituted C1 to C10 alkyl group, -L¹-C═C(R⁶)(R⁷), or -L²-C≡C(R⁸),
at least one selected from R³ and R⁴ is a substituted or unsubstituted C1 to C10 alkyl group, -L¹-C═C(R⁶)(R⁷), or -L²-C≡C(R⁸),
R⁵ is a substituted or unsubstituted C1 to C10 alkyl group, -L¹-C═C(R⁶)(R⁷), or -L²-C≡C(R⁸),
L¹ and L² are a substituted or unsubstituted C1 to C6 alkylene group, and
R⁶ to R⁸ are each independently hydrogen, a substituted or unsubstituted C1 to C10 alkyl group, a substituted or unsubstituted C2 to C10 alkenyl group, or a substituted or unsubstituted C2 to C10 alkynyl group.

9. The semiconductor photoresist composition as claimed in claim 1, wherein:
the organometallic compound represented by Chemical Formula 1 is selected from among the compounds listed in Group 1:

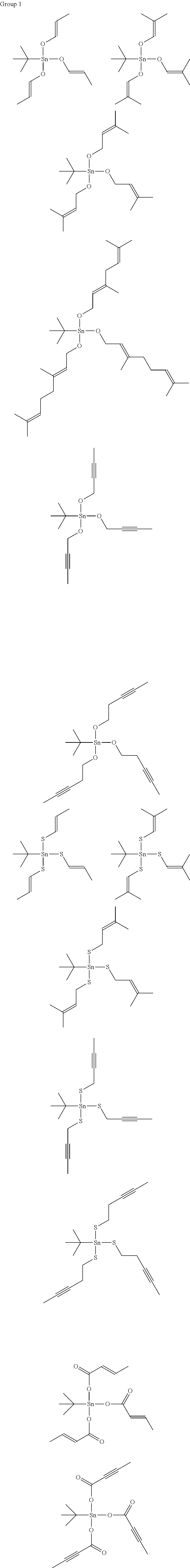

10. The semiconductor photoresist composition as claimed in claim 1, wherein:
the organometallic compound represented by Chemical Formula 1 is in an amount of 0.5 wt % to 30 wt % based on 100 wt % of the semiconductor photoresist composition.

11. The semiconductor photoresist composition as claimed in claim 1, further comprising other additives of a surfactant, a crosslinking agent, a leveling agent, an organic acid, a quencher, or a combination thereof.

12. The semiconductor photoresist composition as claimed in claim 11, wherein:
the surfactant comprises at least one selected from among an alkyl benzene sulfonate salt, an alkyl pyridinium salt, polyethylene glycol, a quaternary ammonium salt, and a combination thereof.

13. The semiconductor photoresist composition as claimed in claim 11, wherein:
the crosslinking agent comprises at least one selected from among a melamine-based crosslinking agent, a substituted urea-based crosslinking agent, an acryl-based crosslinking agent, an epoxy-based crosslinking agent, a polymer-based crosslinking agent, and a combination thereof.

14. The semiconductor photoresist composition as claimed in claim 11, wherein:
the organic acid comprises at least one selected from among p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and a combination thereof.

15. The semiconductor photoresist composition as claimed in claim 11, wherein:
the quencher comprises at least one selected from among diphenyl (p-tolyl) amine, methyl diphenyl amine, triphenyl amine, phenylenediamine, naphthylamine, diaminonaphthalene, and a combination thereof.

16. The semiconductor photoresist composition as claimed in claim 1, wherein:
the solvent comprises at least one selected from among an aromatic compound, an alcohol, an ether, an ester, a ketone, and a combination thereof.

17. A method of forming patterns, comprising:
forming an etching-objective layer on a substrate;
coating the semiconductor photoresist composition as claimed in claim 1 on the etching-objective layer to form a photoresist film;
exposing and developing the photoresist film to form a photoresist pattern on the photoresist film; and
etching the etching-objective layer utilizing the photoresist pattern as an etching mask.

18. The method as claimed in claim 17, wherein:
the exposing and developing of the photoresist film is performed utilizing light having a wavelength in a range of 5 nm to 150 nm.

19. The method as claimed in claim 17, wherein:
the photoresist pattern has a width in a range of 5 nm to 100 nm.

20. The method as claimed in claim 17, wherein:
the photoresist pattern has a pitch having a half-pitch of less than or equal to 50 nm and a line width roughness of less than or equal to 5 nm.
